(19) United States
(12) Patent Application Publication
(10) Pub. No.: US 2026/0344398 A1
(43) Pub. Date: Oct. 29, 2026

(54) SELF-ALIGNED VIA STRUCTURE AND THE METHODS OF FORMING THE SAME

(71) Applicant: Taiwan Semiconductor Manufacturing Company, Ltd., Hsinchu (TW)

(72) Inventors: Shimpei Yamaguchi, Tsukuba (JP); Kinya Ichikawa, Tsukuba (JP); Guillermo Fernandez Zapico, Tsukuba (JP)

(21) Appl. No.: 19/732,946

(22) Filed: Jul. 7, 2026

Related U.S. Application Data
(63) Continuation of application No. 18/971,519, filed on Dec. 6, 2024.
(60) Provisional application No. 63/675,885, filed on Jul. 26, 2024.

(51) Int. Cl. H10W 20/42; H10W 20/00; H10W 20/41; H10W 70/65

(52) U.S. Cl. CPC H10W 20/42; H10W 20/058; H10W 20/069; H10W 20/435; H10W 70/65

(57) ABSTRACT

A method includes forming a first metal line, forming a dielectric layer, with the first metal line being in the dielectric layer, and etching back the first metal line to form a trench in the dielectric layer. A lower part of the first metal line remains under the trench. The method further includes filling a photo sensitive material in the trench, and performing a photolithography process to pattern the photo sensitive material. A via opening is formed in the dielectric layer and the photo sensitive material. A second metal line and a via are formed, wherein the via is formed in the via opening, and the second metal line is over and joined to the via.

### PRIORITY CLAIM AND CROSS-REFERENCE

This application is a continuation of U.S. patent application Ser. No. 18/971,519, entitled “SELF-ALIGNED VIA STRUCTURE AND THE METHODS OF FORMING THE SAME,” filed on Dec. 6, 2024, which claims the benefit of the following provisionally filed U.S. Patent application: Application No. 63/675,885, filed on Jul. 26, 2024, and entitled “SELF-ALIGNED VIA STRUCTURE FOR FINE PITCH RDL,” which application are hereby incorporated herein by reference.

### BACKGROUND

In the formation of integrated circuits, redistribution structures are often used for interconnecting device dies and rerouting electrical signals. The redistribution structures often include a plurality of layers of redistribution lines. The plurality of layers of redistribution lines are interconnected through vias, which are formed as the lower portions of the redistribution lines. For example, a lower redistribution line may include a metal pad. A dielectric layer is formed over the metal pad. An upper redistribution lines includes a via in the dielectric layer, and a line portion over the dielectric layer. The via has a length and width smaller than that of the metal pad in order to be able to land on the metal pad.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 illustrate the formation of a redistribution structure in accordance with some embodiments.

FIGS. 3A, 3B, and 3C through FIGS. 8A, 8B, and 8C illustrate the formation of a lower redistribution line and a via opening offset from line end of an underlying metal line in accordance with some embodiments.

FIGS. 9A, 9B, and 9C through FIGS. 14A, 14B, and 14C illustrate the formation of a lower redistribution line and a via opening aligned to a line end of an underlying metal line in accordance with some embodiments.

FIGS. 15A, 15B, and 15C through FIGS. 18A, 18B, and 18C illustrate the formation of an upper redistribution line having a lengthwise direction different from a lengthwise direction of a lower redistribution line in accordance with some embodiments.

FIGS. 19A, 19B, and 19C through FIGS. 22A, 22B, and 22C illustrate the formation of an upper redistribution line having a lengthwise direction parallel to a lengthwise direction of a lower redistribution line in accordance with some embodiments.

FIGS. 23 through 26 illustrate the formation of a package based on the redistribution structure in accordance with some embodiments.

FIGS. 27A, 27B, and 27C illustrate the cross-sectional views of several metal lines and the overlying vias in accordance with some embodiments.

FIG. 28 illustrates a process flow for forming a redistribution line in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A redistribution structure and the method of forming the same are provided. In accordance with some embodiments of the present disclosure, a metal line is formed, and is located in a first dielectric layer. The metal line is recessed to form a trench in the first dielectric layer. A dielectric material is filled into the trench, and is patterned to form a via opening. The dielectric material may be formed of a photo sensitive material. A redistribution line is then formed, with a via of the redistribution line being formed in the via opening. The via, defined by the trench, thus has edges vertically aligned to the respective edges of the underlying recessed metal line. The via is thus self-aligned to the metal line, and the metal line does not need to have a larger pad for the via to land thereon. The minimum pitch of the redistribution lines thus may be reduced, and the density of the redistribution lines is increased.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

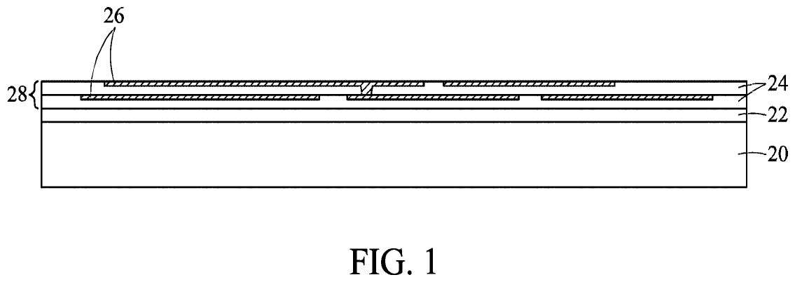

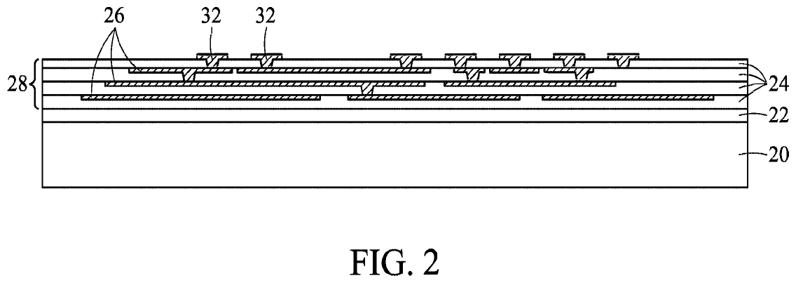

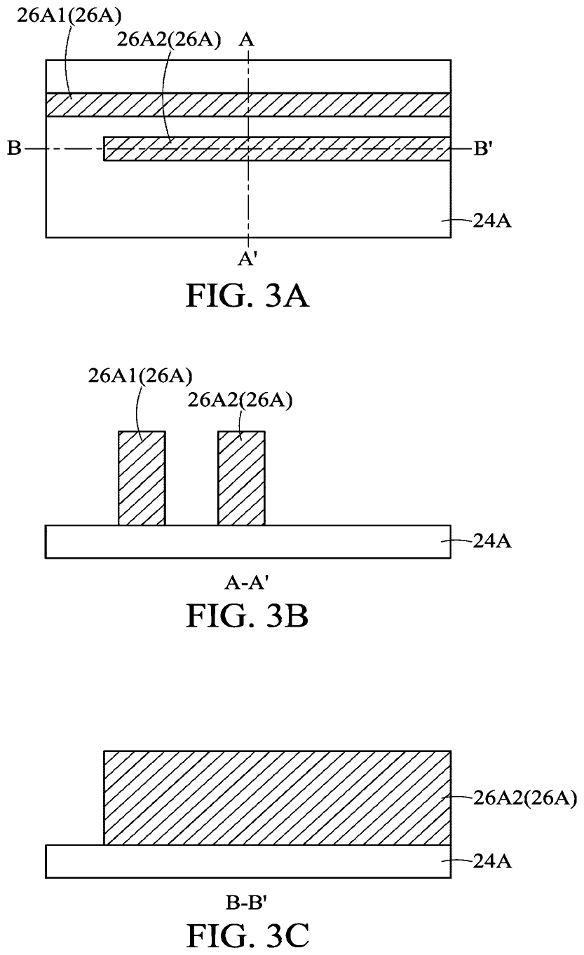

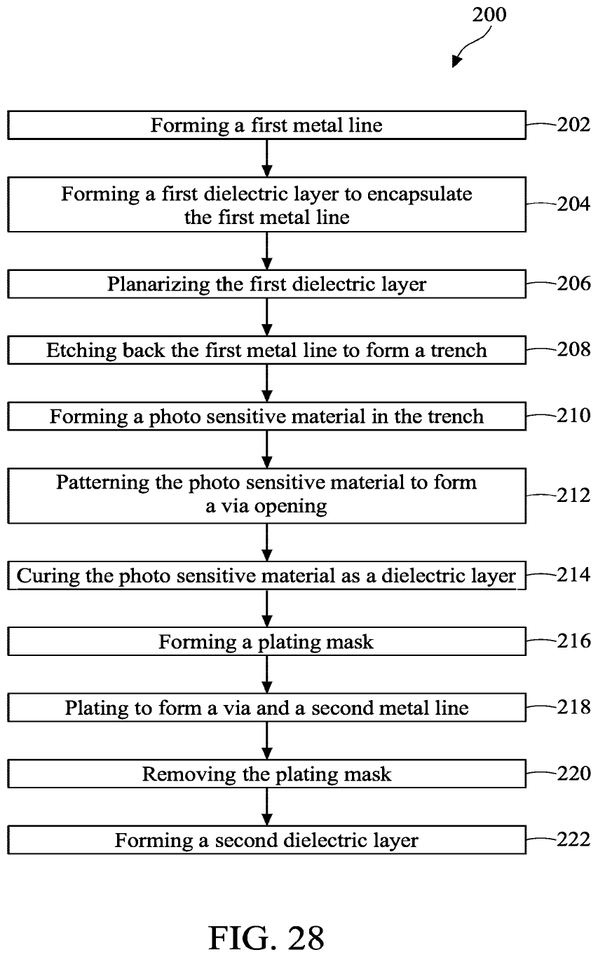

FIGS. 1 and 2 illustrate the cross-sectional views of intermediate stages in the formation of a redistribution structure in accordance with some embodiments of the present disclosure. The details of forming redistribution lines and dielectric layers in the redistribution structure are illustrated in FIGS. 3A, 3B, 3C through FIGS. 22A, 22B, and 22C. The corresponding processes of some of the embodiments are also reflected schematically in the process flow 200 as shown in FIG. 28.

FIG. 1 illustrates carrier 20, and release film 22 formed on carrier 20. Carrier 20 may be a glass carrier, a silicon wafer, an organic carrier, or the like. Release film 22 may be formed of a polymer-based material and/or an epoxy-based thermal-release material (such as a Light-To-Heat-Conversion (LTHC) material), which is capable of being decomposed under radiation such as a laser beam, so that carrier 20 may be de-bonded from the overlying structures that will be formed in subsequent processes. In accordance with some embodiments, release film 22 is applied on carrier 20 through spin-coating or adhesion.

Further referring to FIG. 1, a part of redistribution structure 28, which includes a plurality of dielectric layers 24 and a plurality of Redistribution Lines (RDLs) 26, is formed over the release film 22. Redistribution structure 28 is alternatively referred to as an interposer 28. Interposer 28 may be an organic interposer comprising organic dielectric layers and redistribution lines.

In accordance with some embodiments, redistribution structure 28 is formed layer-by-layer starting from release film 22. The formation process of a lower RDL and an upper RDL is illustrated in detail in FIGS. 3A, 3B, 3C through FIGS. 22A, 22B, and 22C, as will be discussed in subsequent paragraphs.

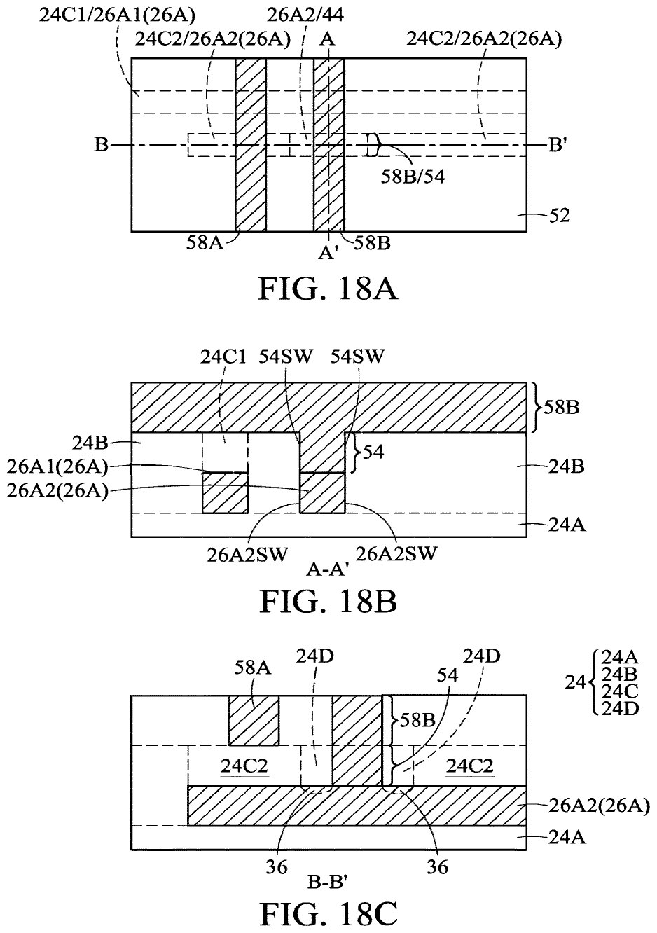

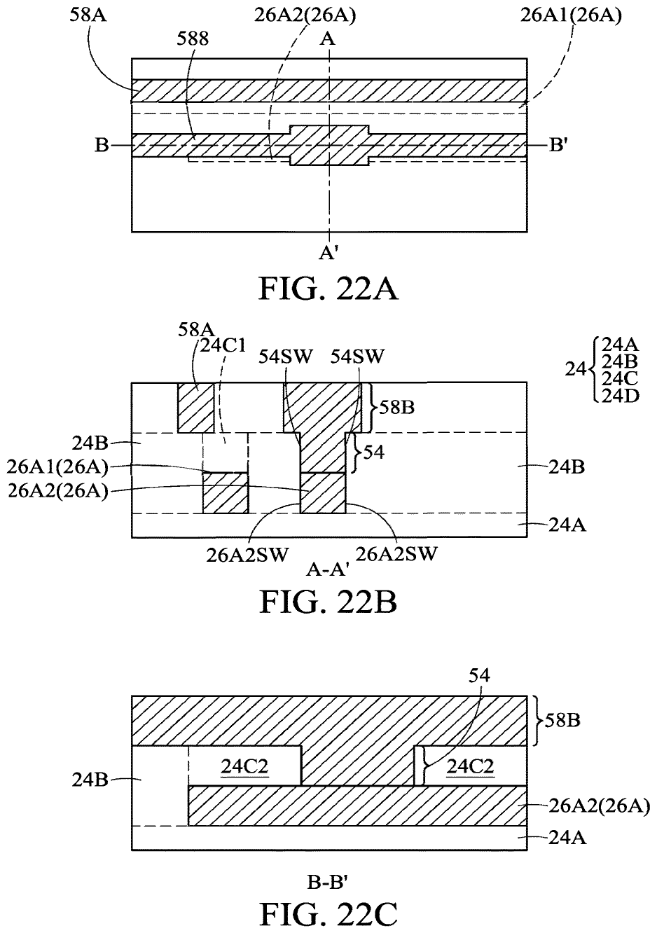

FIG. 2 illustrates the formation of additional dielectric layers 24 and additional RDLs 26 to extend redistribution structure. Throughout the description, the subsequently formed dielectric layers 24A, 24B, 24C, and 24D (as shown in FIGS. 18B and 18C or FIGS. 22B and 22C) are individually and collectively referred to as dielectric layers 24, and RDLs 26A are also referred to as RDLs 26.

After the formation of a top dielectric layer in redistribution structure 28, electrical connectors 32 may be formed. Electrical connectors 32 may be formed of or comprise micro-bumps, metal pads, metal pillars, Under-Bump-Metallurgies (UBMs), solder regions, and/or the like. The formation of electrical connectors 32 may also be similar to the formation of RDLs, which formation process may include patterning the top dielectric layer 24 to expose the underlying RDLs 26, depositing a metal seed layer, forming a patterned plating mask, performing one or a plurality of plating processes to form electrical connectors 32, removing the plating mask, and etching the metal seed layer. Electrical connectors 32 may include copper, aluminum, cobalt, nickel, gold, silver, tungsten, solder, alloys thereof, and/or multi-layers thereof.

FIGS. 3A, 3B, and 3C through FIGS. 8A, 8B, and 8C illustrate the formation of a lower redistribution line in the redistribution structure 28 and a via opening in accordance with some embodiments. The via opening is vertically aligned to an intermediate portion (and is offset from line ends) of the lower redistribution line.

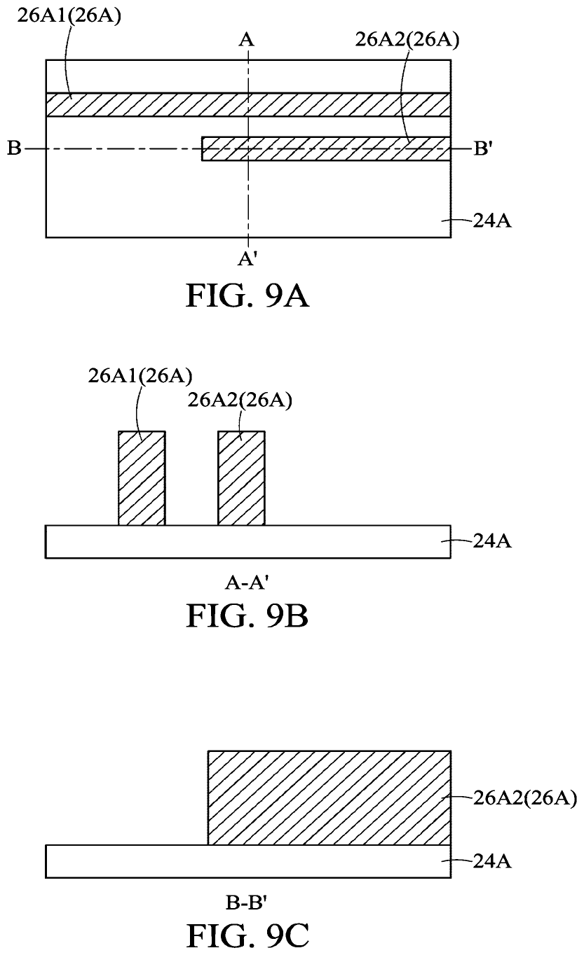

FIGS. 9A, 9B, and 9C through FIGS. 14A, 14B, and 14C illustrate the formation of a lower redistribution line in the redistribution structure and a via opening in accordance with alternative embodiments. The via opening is vertically aligned to a line end of the lower redistribution line.

It is appreciated that the embodiments as shown in FIGS. 3A, 3B, and 3C through FIGS. 8A, 8B, and 8C may be performed simultaneously as the embodiments shown in FIGS. 9A, 9B, and 9C through FIGS. 14A, 14B, and 14C. Accordingly, in the same device die, some via openings are aligned to the intermediate portions of the respective lower redistribution lines, while some other via openings are aligned to the line-end portions of the respective lower redistribution lines.

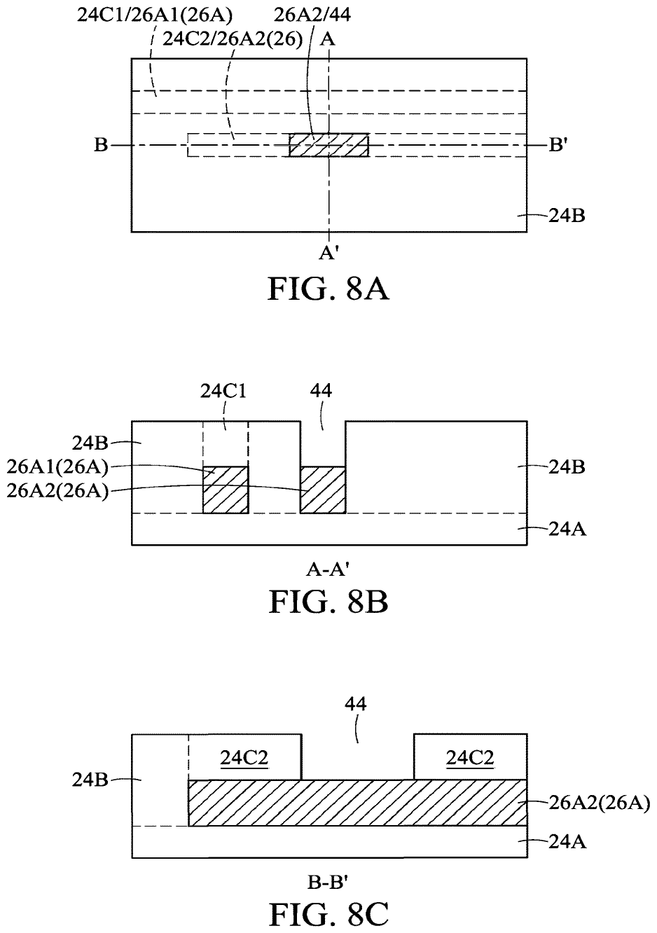

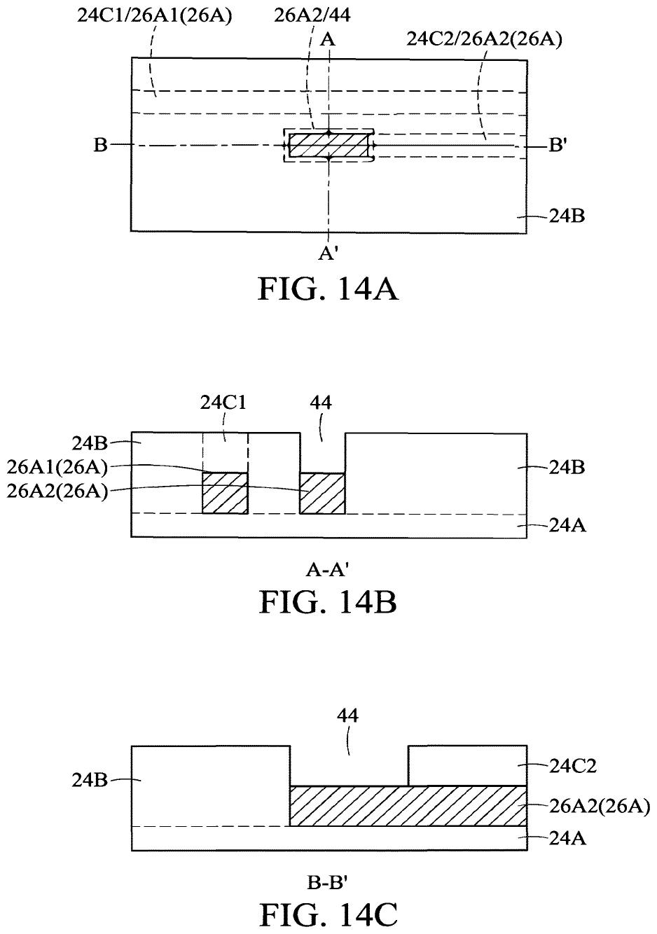

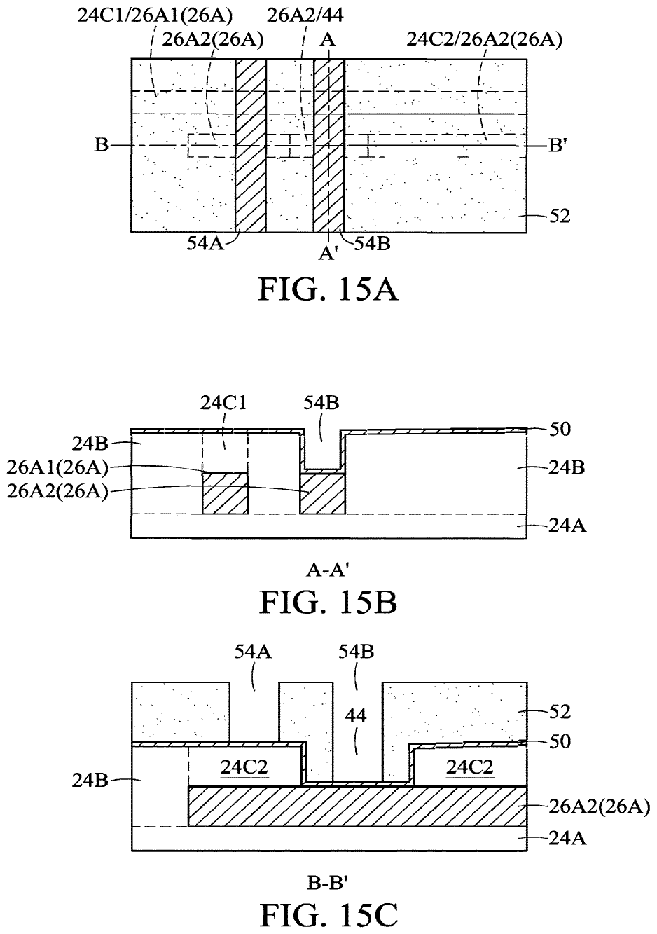

FIGS. 15A, 15B, and 15C through FIGS. 18A, 18B, and 18C illustrate the formation of an upper redistribution line in accordance with some embodiments. The upper redistribution line has a lengthwise direction different from a lengthwise direction of the lower redistribution line. The upper redistribution line includes a via in the via opening as shown in FIGS. 8B and 8C or the via opening as shown in FIGS. 14B and 14C.

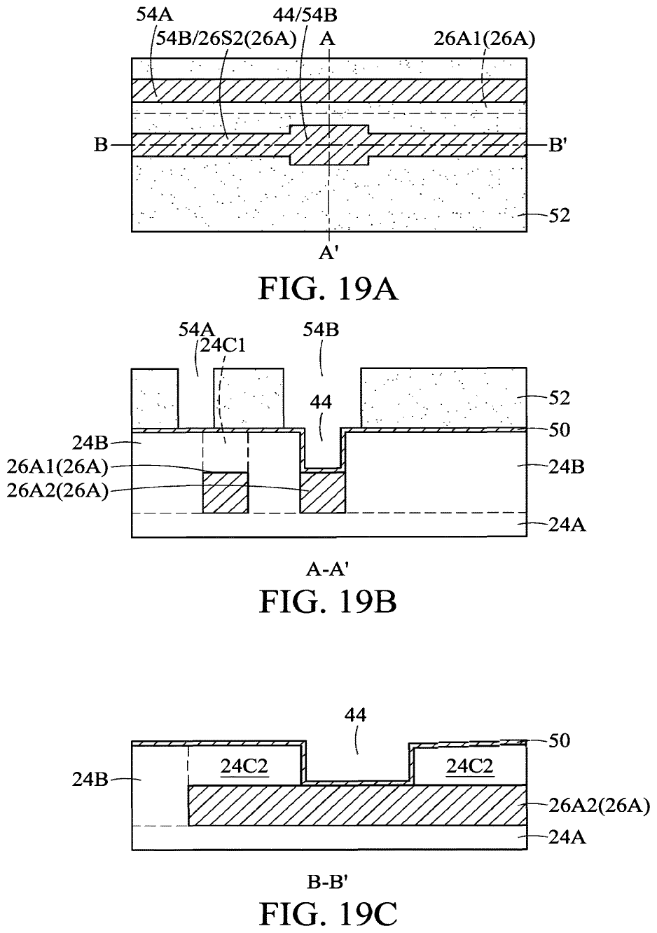

FIGS. 19A, 19B, and 19C through 22A, 22B, and 22C illustrate the formation of an upper redistribution line in accordance with alternative embodiments. The upper redistribution line has a lengthwise direction parallel to a lengthwise direction of the lower redistribution line. The upper redistribution line may also include a via in the via opening as shown in FIGS. 8B and 8C or the via opening as shown in FIGS. 14B and 14C.

Alternatively stated, each of the embodiments shown in FIGS. 3A, 3B, and 3C through FIGS. 8A, 8B, and 8C and the embodiment shown in FIGS. 9A, 9B, and 9C through FIGS. 14A, 14B, and 14C may be combined with either the embodiment shown in FIGS. 15A, 15B, and 15C through FIGS. 18A, 18B, and 18C or the embodiment shown in FIGS. 19A, 19B, and 19C through FIGS. 22A, 22B, and 22C.

It is appreciated that the embodiments of shown in FIGS. 15A, 15B, and 15C through 18A, 18B, and 18C may be performed simultaneously as the embodiments shown in FIGS. 19A, 19B, and 19C through 22A, 22B, and 22C. Accordingly, in the same device die, some vias are aligned to the intermediate portions of the respective lower redistribution lines, while some other vias are aligned to the line-end portions of the respective lower redistribution lines.

The subsequent figures may be denoted with a number followed by letter A, B, or C. The figures with the notation including letter A illustrate the top views of the structure. The figures with the notation including letter B illustrate the cross-sectional views of the structure, which cross-sectional views illustrate the cross-section A-A′ of the respective top view. The figures with the notation including letter C illustrate the cross-sectional views of the structure, which cross-sectional views illustrate the cross-section B-B′ of the respective top view.

FIGS. 3A, 3B, and 3C illustrate the top view and cross-sectional views in the formation of an initial structure in accordance with some embodiments. Dielectric layer 24A is formed, and RDLs 26A1 and 26A2 (also referred to as metal lines) are formed over dielectric layer 24A. The dielectric layer 24A in FIGS. 3A, 3B, and 3C may be any of the dielectric layers 24 (FIG. 2) over which a redistribution line is formed.

In accordance with some embodiments, dielectric layer 24A may be formed of or comprise a photo sensitive material such as polyimide, polybenzoxazole (PBO), benzocyclobutene (BCB), or the like. At the time RDLs 26A1 and 26A2 have been formed, the dielectric layer 24A has been cured, and thus is no longer photo sensitive, which means that a photo exposure process and a subsequent development process performed on the dielectric layer 24A will not be able to pattern the dielectric layer 24A.

In accordance with some embodiments, RDLs 26A1 and 26A2, which are individually and collectively referred to as RDLs 26A, are formed over dielectric layer 24A. The respective process is illustrated as process 202 in the process flow 200 as shown in FIG. 28. The lengthwise directions of RDLs 26A1 and 26A2 are parallel to each other. While not illustrated in FIGS. 3B and 3C, RDLs 26A1 and 26A2 may (or may not) include vias in dielectric layer 24A. The height (thickness) of RDLs 26A1 and 26A2 are intentionally formed as greater than the intended thickness of RDLs 26 in the final structure (FIG. 2). For example, the thickness of RDLs 26A1 and 26A2 may be equal to or greater than the sum of the thickness of RDLs 26A1 and 26A2 in the final structure plus the height (thickness) of the overlying vias.

RDLs 26A1 and 26A2 may be formed of or comprise copper, nickel, titanium, tungsten, or the like. For example, RDLs 26A1 and 26A2 may comprise a titanium seed layer and a copper layer over the titanium seed layer. The formation process of RDLs 26A1 and 26A2 may include forming a metal seed layer (not shown), which includes some portions over dielectric layer 24A. Dielectric layer 24A may (or may not) include openings therein. The metal seed layer may extend into dielectric layer 24A when via openings are formed in dielectric layer 24A. The metal seed layer may be formed using, for example, Physical Vapor Deposition (PVD) or a like process.

A patterned plating mask (not shown) such as a photoresist may then be formed over the metal seed layer, followed by a metal plating process to deposit a metallic material on the exposed metal seed layer. The patterned plating mask and the portions of the metal seed layer covered by the patterned plating mask are then removed, leaving RDLs 26A as shown in FIGS. 3A, 3B, and 3C. The plated material may include copper, aluminum, cobalt, nickel, gold, silver, tungsten, or alloys thereof. The plating process may be performed using, for example, an electrochemical plating process.

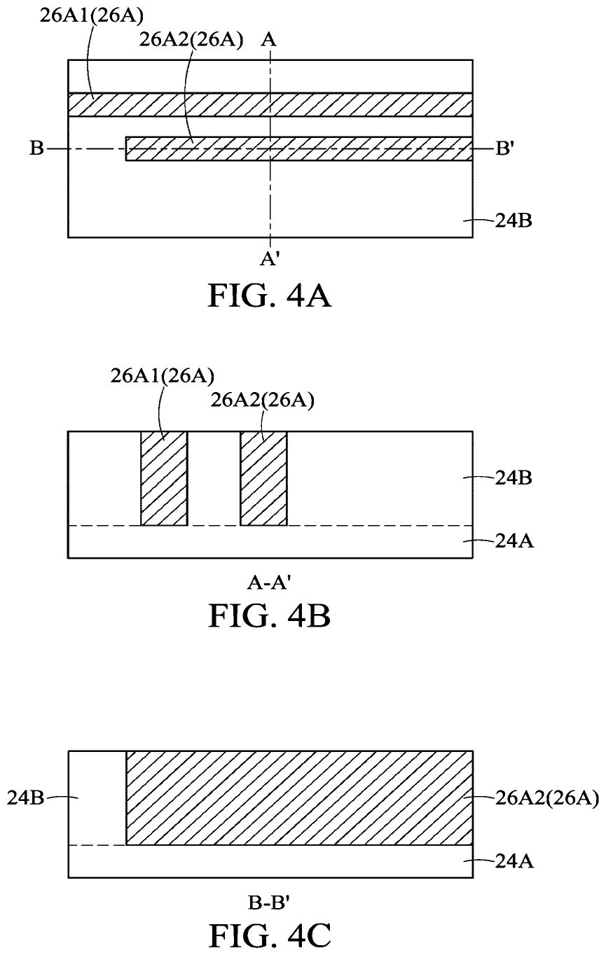

Referring to FIGS. 4A, 4B, and 4C, dielectric layer 24B is formed. The respective process is illustrated as process 204 in the process flow 200 as shown in FIG. 28. Dielectric layer 24B may be formed of a same material as dielectric layer 24A in accordance with some embodiments. In the resulting structure, dielectric layers 24A and 24B may be distinguishable from each other (for example, with a noticeable interface in between) or not distinguishable from each other. Alternatively, dielectric layer 24B may be formed of a different material than the material of dielectric layer 24A. Accordingly, in the resulting structure, dielectric layer 24A and 24B are distinguishable from each other.

In accordance with some embodiments, dielectric 24B is formed of or comprises an organic material, which may be a photo sensitive polymer such as polyimide, PBO, BCB, or the like. The formation of dielectric 24B may include dispensing the dielectric 24B in a flowable form, and curing the dielectric 24B into a solid. A planarization process such as a Chemical Mechanical Polish (CMP) process or a mechanical polish process is then performed to level the top surface of dielectric layer 24B with RDLs 26A1 and RDLs 26A2. The respective process is illustrated as process 206 in the process flow 200 as shown in FIG. 28. Being cured, dielectric 24B is no longer photo sensitive.

In accordance with alternative embodiments, dielectric 24B may be formed of a non-photo-sensitive material such as a non-photo-sensitive organic material (such as a polymer) or an inorganic dielectric material. For example, dielectric 24B may be formed of or comprise silicon oxide, silicon nitride, silicon oxynitride, silicon carbide, or the like, or combinations thereof.

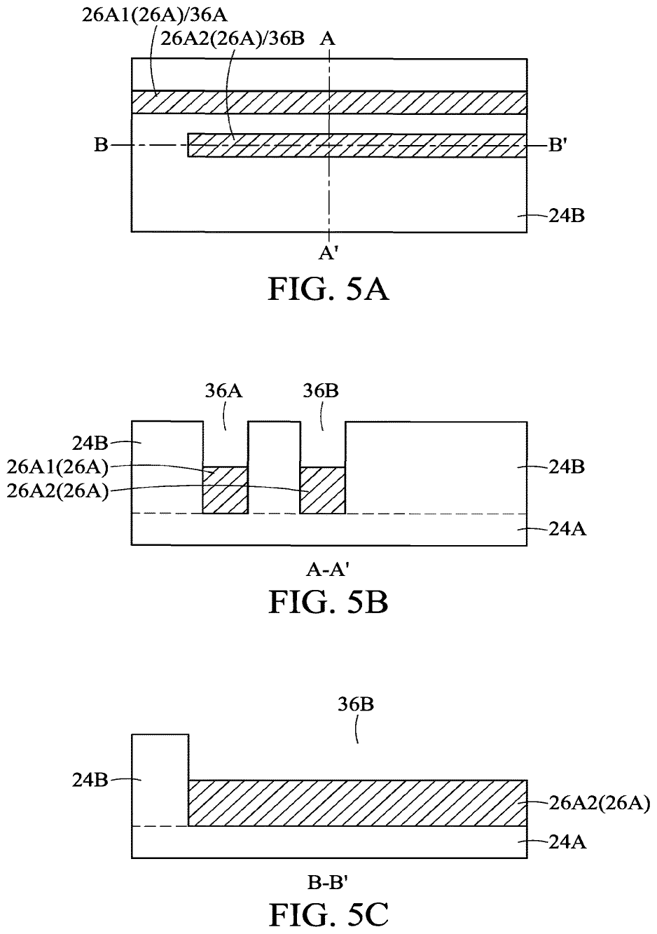

FIGS. 5A, 5B, and 5C illustrate the top view and cross-sectional views in the recessing of RDLs 26A1 and 26A2 in accordance with some embodiments. As shown in FIGS. 5B and 5C, RDLs 26A1 and 26A2 are etched back (recessed) through an etching process, so that trenches 36A and 36B are formed. The respective process is illustrated as process 208 in the process flow 200 as shown in FIG. 28. In accordance with some embodiments, the recessing depth is in a range between about 30 percent and about 70 percent of the height of RDLs 26A1 and 26A2.

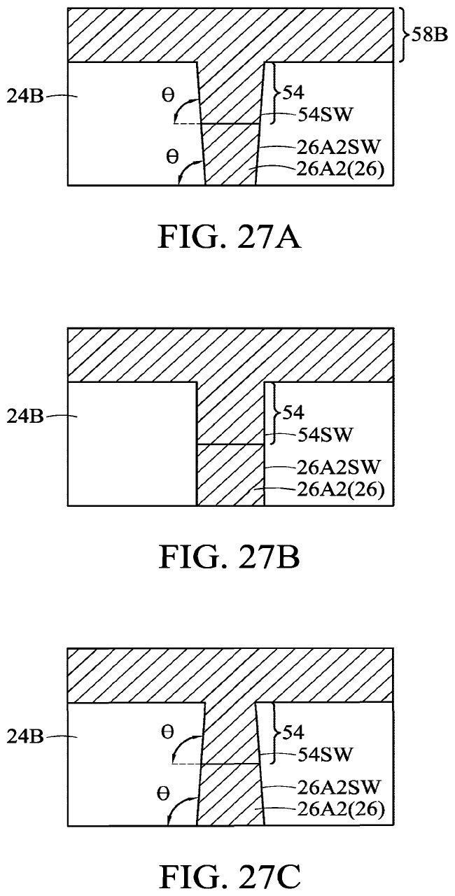

The recessing is performed using an etchant that attacks RDLs 26A 1 and 26A2, but does not attack dielectric layer 24B. Accordingly, the trenches 36A and 36B are formed as being self-aligned to RDLs 26A1 and 26A2, with the edges of the sidewalls of dielectric layer 24B exposed to trenches 36A and 36B being vertically aligned to the edges of the respective underlying RDLs 26A1 and 26A2. When the edges of RDLs 26A1 and 26A2 as shown in FIG. 4B are slanted and straight (For example, having the profile same as that shown in FIGS. 27A and 27C), the sidewalls of dielectric layer 24B exposed to trenches 36A and 36B as shown in FIG. 5B are also slanted and straight.

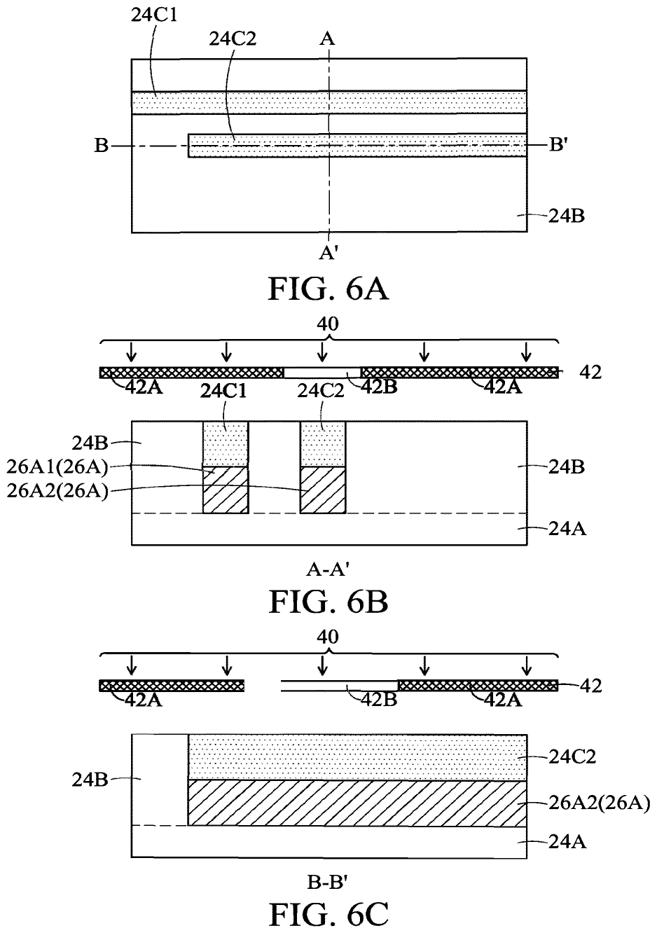

FIGS. 6A, 6B, and 6C illustrate the top view and cross-sectional views in the filling of trenches 36A and 36B in accordance with some embodiments. In accordance with some embodiments, a photo sensitive material (which may include a polymer) such as polyimide, PBO, or the like, is dispensed into trenches 36A and 36B in a flowable form. The respective process is illustrated as process 210 in the process flow 200 as shown in FIG. 28. The photo sensitive material is baked into solid. The baked photo sensitive material, however, is not cured, so that the photo sensitive material remains to be photo sensitive.

A planarization process such as a CMP process or a mechanical polishing process is then performed to level the top surface of the photo sensitive material with the top surface of dielectric layer 24B. The remaining portions of the photo sensitive material are photo sensitive strips 24C1 and 24C2.

In the above process, dielectric layer 24B acts as a mold to define the shapes and sizes of photo sensitive strips 24C1 and 24C2. The top portions of RDLs 26A1 and 26A2 that are etched in the preceding process define the shapes and the sizes of photo sensitive strips 24C1 and 24C2.

Next, as also illustrated by FIGS. 6B and 6C, a photo lithography mask 42 is placed over the precedingly formed structure including dielectric layer 24B and photo sensitive strips 24C1 and 24C2. Photo lithography mask 42 includes opaque portions for blocking light, and transparent portions allowing light to pass through. In the following discussion, it is assumed that the photo sensitive strips 24C1 and 24C2 comprise a positive photoresist, and thus portions 42B are transparent portions, while portions 42A are opaque portions. It is appreciated that the photo sensitive strips 24C1 and 24C2 may also comprise a negative photoresist, and the patterns of the opaque portions and transparent portions of lithography mask 42 will be inverted.

In accordance with some embodiments, as shown in FIGS. 6B and 6C, the opaque portions 42A are directly over and overlap photo sensitive strip 24C1 and some portions of photo sensitive strip 24C2. A portion of photo sensitive strip 24C2 is directly underlying and overlapped by a transparent portion 42B.

A light exposure process 40 is then performed to light-expose a portion of photo sensitive strip 24C2 that is directly underlying the transparent portion 42B. In the cross-sectional view as shown in FIG. 6B, the transparent portion 42B is oversized, and is wider than, and extends laterally beyond, the edges of the underlying photo sensitive strip 24C2 to ensure that the underly portion of photo sensitive strip 24C2 is light-exposed from edge to edge even if lithography misalignment occurs. Since dielectric layer 24B has been cured (if initially formed of a photo sensitive material), although some portions of dielectric layer 24B are exposed to light, the exposed portions of dielectric layer 24B will not be removed in the subsequent development process.

In the cross-sectional view as shown in FIG. 6C, the transparent portion 42B overlaps an intermediate portion of RDL 26A2, and RDL 26A2 laterally extends beyond the opposing edges of transparent portion 42B.

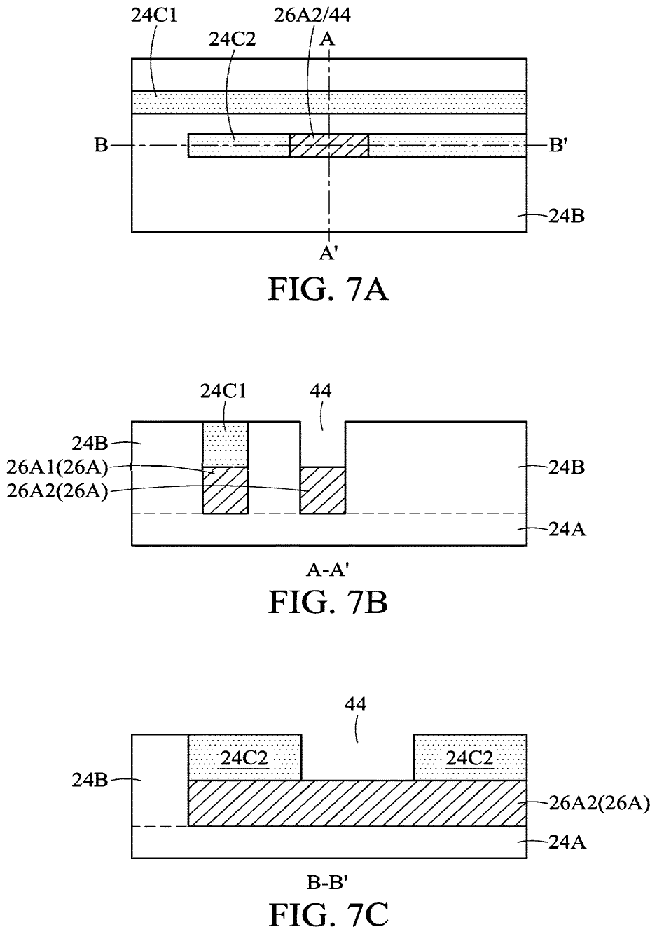

FIGS. 7A, 7B, and 7C illustrate the top view and cross-sectional views after the development of photo sensitive strips 24C1 and 24C2. The light-exposed portion of photo sensitive strip 24C2 is removed, forming via opening 44. The respective process is illustrated as process 212 in the process flow 200 as shown in FIG. 28. As shown in FIG. 7B, via opening 44 is self-aligned to the underlying RDL 26A2. As shown in FIG. 7C, via opening 44 is aligned to an intermediate portion of RDL 26A2, and is vertically offset from the line ends of RDL 26A2.

In a subsequent process, as shown in FIGS. 8A, 8B, and 8C, a curing process is performed on photo sensitive strips 24C1 and 24C2, so that photo sensitive strips 24C1 and 24C2 are no longer photo sensitive, and is converted as a dielectric layer in the resulting structure. The respective process is illustrated as process 214 in the process flow 200 as shown in FIG. 28. Throughout the description, photo sensitive strips 24C1 and 24C2 are alternatively referred to as dielectric strips 24C1 and 24C2. The resulting dielectric strips 24C1 and 24C2 may comprise a same dielectric material as, or a different dielectric material than, the material of dielectric layer 24B. The resulting dielectric strips 24C1 and 24C2 may be (or may not be) distinguishable from dielectric layer 24B. Accordingly, the interfaces between dielectric layer 24B and dielectric strips 24C1 and 24C2 are illustrated as being dashed.

In above-discussed embodiments as shown in FIGS. 3A, 3B, 3C through FIGS. 8A, 8B, and 8C, the via opening 44 (which is vertically aligned to an intermediate portion (rather than aligned to a line-end portion) of the underlying RDL 26A2) is formed. FIGS. 9A, 9B, 9C through FIGS. 14A, 14B, and 14C illustrate some alternative embodiments for forming a via opening 44 that is vertically aligned to a line-end portion of the underlying RDL 26A2. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

FIGS. 9A, 9B, and 9C illustrate a top view and cross-sectional views of an initial structure, in which dielectric layer 24A has been formed, and RDLs 26A1 and 26A2 (individually and collectively referred to as RDLs 26A) are formed over dielectric layer 24A. The details of materials, structures, and formation methods of dielectric layer 24A and RDLs 26A1 and 26A2 may be found referring to the discussion in the preceding embodiments, and are not repeated herein.

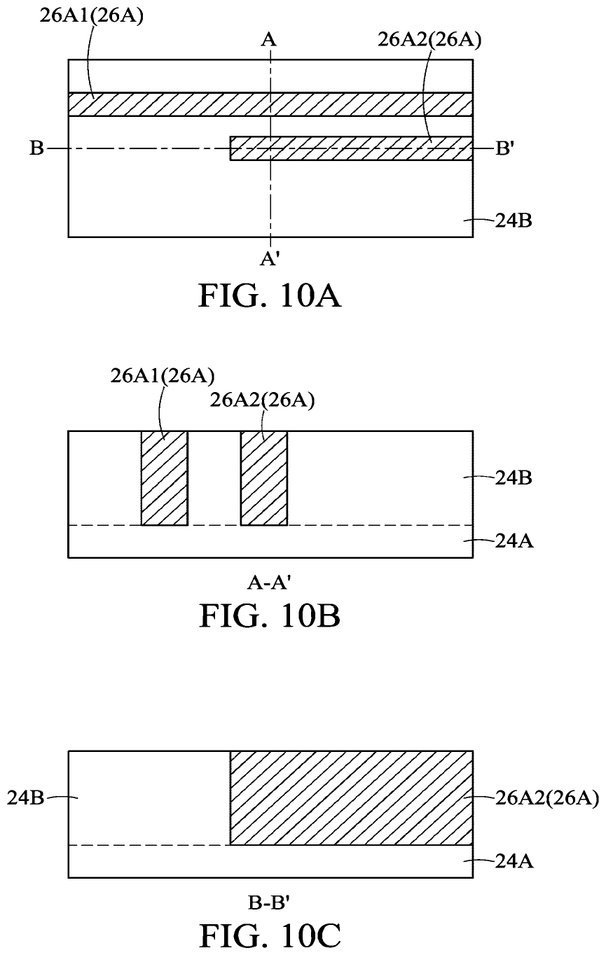

FIGS. 10A, 10B, and 10C illustrate a top view and cross-sectional views in the formation of dielectric layer 24B. The material and the formation method of dielectric layer 24B have been discussed in preceding embodiments, and are not repeated herein. For example, dielectric layer 24B may comprise a photo sensitive material, which is dispensed, cured, and polished. Dielectric layer 24B is thus is no longer photo sensitive. Alternatively, dielectric layer 24B may be formed of an inorganic dielectric material.

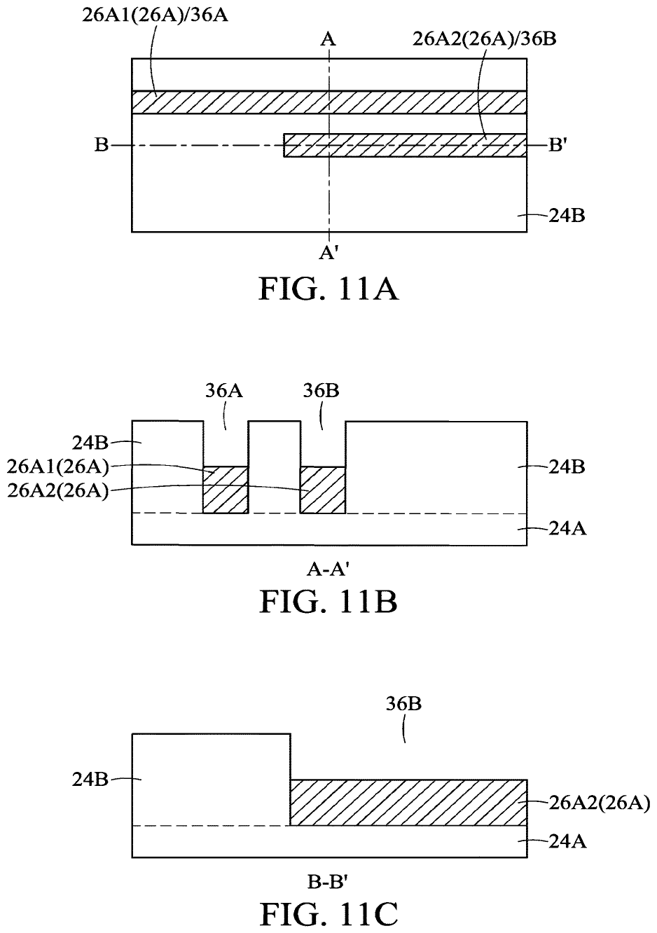

FIGS. 11A, 11B, and 11C illustrate a top view and cross-sectional views in the recessing of RDLs 26A1 and 26A2 to form trenches 36A and 36B, respectively.

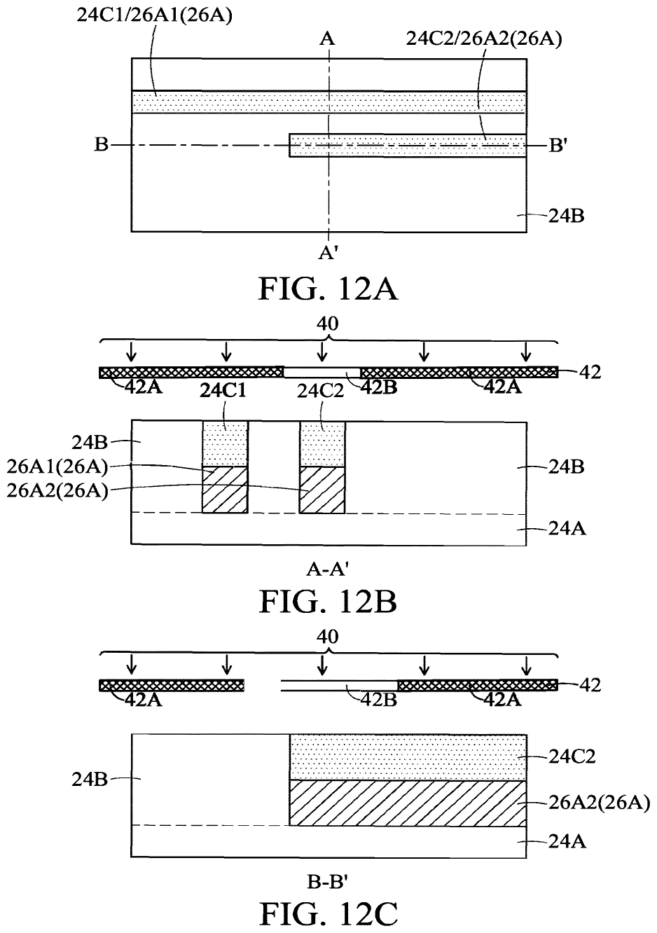

FIGS. 12A, 12B, and 12C illustrate a top view and cross-sectional views in the formation of photo sensitive strips 24C1 and 24C2 in trenches 36A and 36B, respectively. The top surfaces of photo sensitive strips 24C1 and 24C2 may be coplanar with the top surface of dielectric layer 24B, for example, achieved through a planarization process. Photo sensitive strips 24C1 and 24C2 are still photo sensitive in the structure shown in FIGS. 12A, 12B, and 12C.

FIGS. 12B and 12C further illustrate a light-exposure process 40 performed on photo sensitive strips 24C1 and 24C2 in accordance with some embodiments. The light-exposure process 40 is performed using photo lithography mask 42 to define patterns. The light-exposure process 40 and the photo lithography mask 42 are essentially the same as that shown in FIGS. 6B and 6C, except that the transparent portion 42B of the photo lithography mask 42 is aligned to a line end of RDL 26A2, rather than aligned to an intermediate portion of RDL 26A2.

In accordance with some embodiments, in the cross-section as shown in FIG. 12B, the transparent portion 42B is oversized, and extends laterally beyond opposing edges of the photo sensitive strips 24C2. In the cross-section as shown in FIG. 12C, the transparent portion 42B is also oversized, and extends laterally beyond one end of the photo sensitive strips 24C2. Since dielectric layer 24B has been cured (if initially formed of a photo sensitive material), although some portions of dielectric layer 24B are exposed to light, the exposed portions of dielectric layer 24B will not be removed in the subsequent development process.

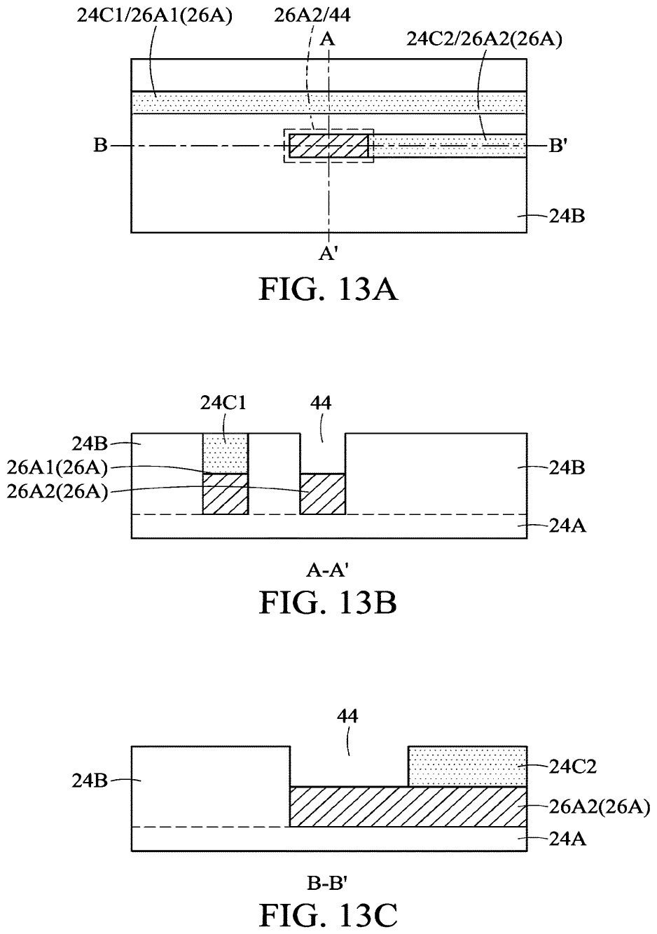

FIGS. 13A, 13B, and 13C illustrate a top view and cross-sectional views in the development of photo sensitive strips 24C1 and 24C2 in accordance with some embodiments. Via opening 44 is thus formed. The light-exposed portion of photo sensitive strip 24C2 is removed, exposing underlying RDL 26A2. Since the light-exposed portion of photo sensitive strip 24C2 is self-aligned to the end sidewall (the illustrated left sidewall) of RDL 26A2, the corresponding via opening 44 has its left end vertically aligned to the left end sidewall of RDL 26A2.

In a subsequent process, as shown in FIGS. 14A, 14B, and 14C, a curing process is performed on photo sensitive strips 24C1 and 24C2, so that photo sensitive strips 24C1 and 24C2 are no longer photo sensitive, and are alternatively referred to as dielectric strips 24C1 and 24C2. The resulting dielectric strips 24C1 and 24C2 may comprise a same dielectric material as, or a different dielectric material than, the material of dielectric layer 24B. The resulting dielectric strips 24C1 and 24C2 may be (or may not be) distinguishable from dielectric layer 24B.

FIGS. 15A, 15B, and 15C through FIGS. 18A, 18B, and 18C illustrate the formation of an upper redistribution line in accordance with some embodiments. The upper redistribution line has a lengthwise direction different from the lengthwise direction of the lower redistribution line 26A 1 and 26A2. The process as shown in FIGS. 15A, 15B, and 15C may be based on the structure shown in FIGS. 8A, 8B, and 8C in the illustrated embodiments, while the process may also be based on the structure shown in FIGS. 14A, 14B, and 14C in accordance with alternative embodiments.

FIGS. 15A, 15B, and 15C illustrate the formation of a metal seed layer 50, which is formed on the structure shown in FIGS. 8A, 8B, and 8C. In accordance with some embodiments, metal seed layer 50 may include a titanium layer and a copper layer over the titanium layer. Metal seed layer 50 is formed through a conformal deposition process such as Physical Vapor Deposition (PVD).

FIG. 15C further illustrates the formation of a mask 52, which may comprise a patterned photoresist in accordance with some embodiments, mask 52 comprises trenches 54A and 54B therein. Mask 52 is also referred to as a plating mask when a plating process is to be performed. The respective process is illustrated as process 216 in the process flow 200 as shown in FIG. 28. Trench 54A is for forming a metal line therein. Trench 54B is for forming a metal line and an underlying via therein.

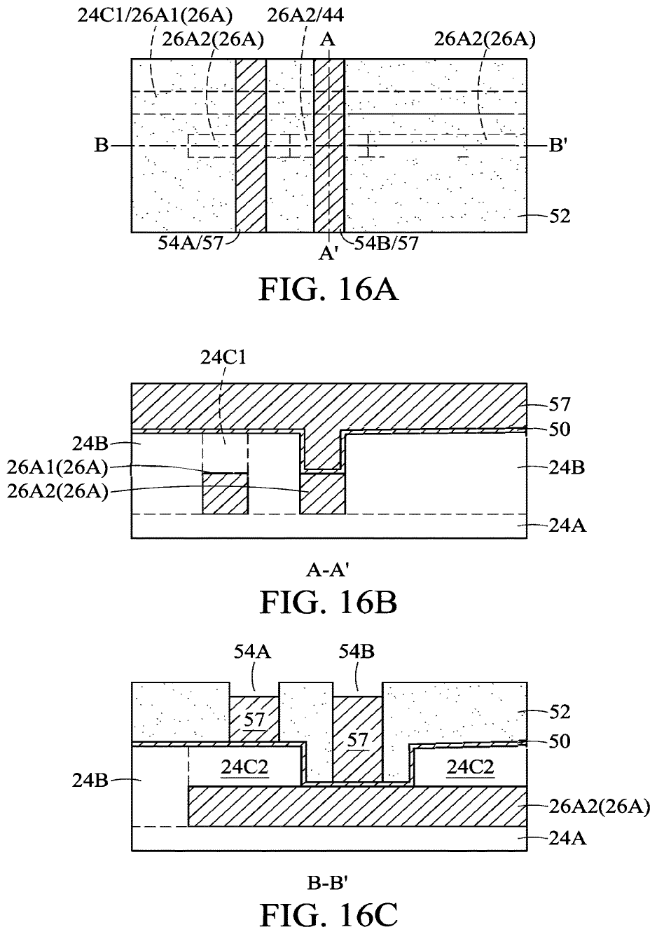

Next, As shown in FIGS. 16A, 16B, and 16C, a metallic material 57 is deposited into the trenches 54A and 54B. The deposition of metallic material 57 may be performed through Electrical Chemical Deposition (ECD), which may comprise an Electrical Chemical Plating (ECP) process in accordance with some embodiments. The respective process is illustrated as process 218 in the process flow 200 as shown in FIG. 28.

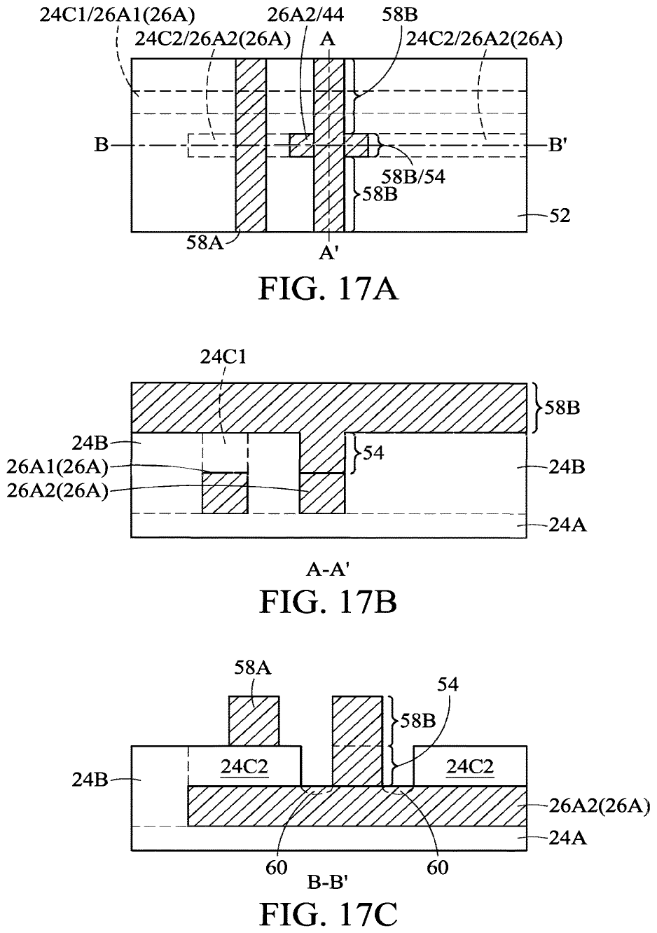

FIGS. 17A, 17B, and 17C illustrate the removal of plating mask 52, so that the underlying portions of metal seed layer 50 are exposed. The respective process is illustrated as process 220 in the process flow 200 as shown in FIG. 28. Next, the exposed portions of metal seed layer 50 that are not directly underlying the metal lines 58A and 58B are removed through etching. The plated metallic material 57 and the underlying metal seed layer 50 collectively form metal lines 58A and 58B and via 54. Metal lines 58A and 58B are higher than dielectric layer 24B. Via 54 is formed underlying and joined to metal line 58B, with no distinguishable interface between via 54 and metal line 58B.

As may be realized from FIGS. 16C and 17C, some portions of metal seed layer 50 are directly over RDL 26A2. Since the properties of RDL 26A2 are closer to the properties of metal seed layer 50 than the properties of dielectric layer 24B, recesses 60 may be formed in RDL 26A2 due to the over-etch of metal seed layer 50. Dashed lines 60 schematically illustrate the top surfaces of the recessed RDL 26A2.

FIGS. 18A, 18B, and 18C illustrate the formation of dielectric layer 24D. The respective process is illustrated as process 222 in the process flow 200 as shown in FIG. 28. In accordance with some embodiments, dielectric layer 24D may be formed of a material selected from the same group of candidate materials for forming dielectric layers 24A, 24B, and/or 24C. The material of dielectric layer 24D may be the same or different from the material of dielectric layers 24A, 24B, and/or 24C.

Dielectric layer 24D may be formed of an organic dielectric material (such as a photo sensitive polymer) or an inorganic dielectric material. Dielectric layers 24A, 24B, and 24D and dielectric strips 24C1 and 24C2 (individually and collectively referred to as dielectric layer 24C) are collectively referred to as dielectric layers 24, as shown in FIG. 2. Some lower portions of dielectric layer 24D may be in dielectric strips 24C2 to contact via 54.

In accordance with the embodiments of the present application, a high degree of alignment can be achieved for aligning the sidewalls of vias 54 to the respective sidewalls of the corresponding underlying metal lines. For example, in the cross-section as shown in FIG. 18B, the sidewall 54SW of via 54 is vertically aligned to the sidewall 26A2SW of metal line 26A2. This is due to the processes in which the metal line 26A2 (FIGS. 10B and 10C) is etched back (FIGS. 11B and 11C) to define the size of via 54. Dielectric layer 24B thus preserves the size of the top part of the metal line 26A2. This process allows for an overlying via formed in subsequent processes to have the same width as the underlying metal line 26A2, without the risk of misalignment.

FIGS. 19A, 19B, and 19C through 22A, 22B, and 22C illustrate the formation of an upper redistribution line in accordance with alternative embodiments. In accordance with these embodiments, the upper redistribution line has a lengthwise direction parallel to (rather than perpendicular to) a lengthwise direction of the lower redistribution lines 26A 1 and 26A2.

Referring to FIGS. 19A, 19B, and 19C, a metal seed layer 50 is formed on the structure shown in FIGS. 8A, 8B, and 8C. In accordance with some embodiments, metal seed layer 50 may include a titanium layer and a copper layer over the titanium layer. Metal seed layer 50 is formed through a conformal deposition process such as Physical Vapor Deposition (PVD). Mask 52 is then formed, with trenches 54A and 54B being formed therein. Mask 52 is also referred to as a plating mask when a plating process is to be performed.

As shown in FIGS. 19A and 19B, in the cross-section A-A′, trench 54B is wider than the underlying via opening 44. This allows for increased process margin in case trench 54B is formed with misalignment from via 0pening 44.

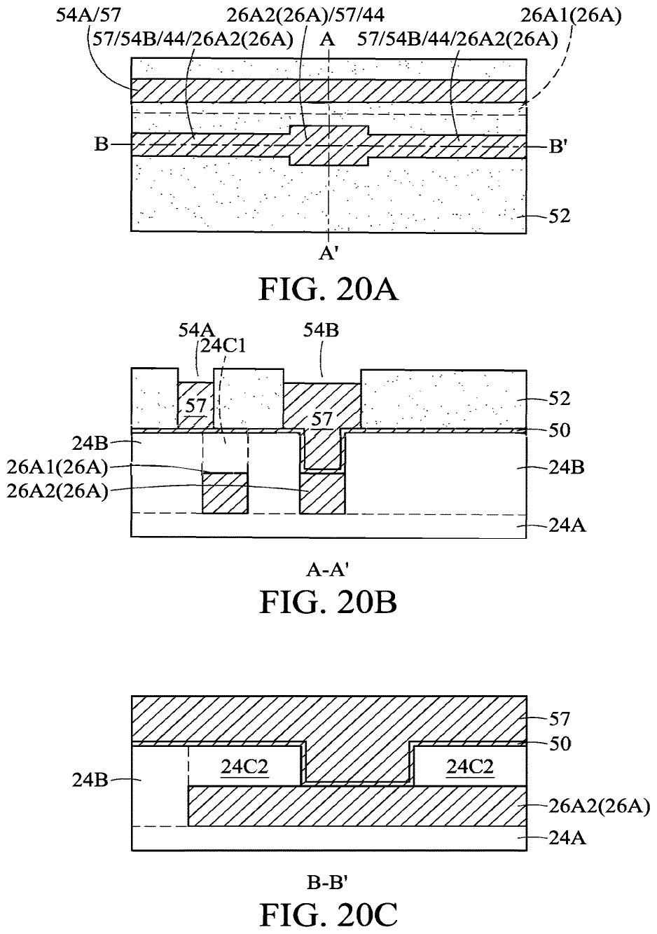

Next, As shown in FIGS. 20A, 20B, and 20C, a metallic material 57 is deposited into the trenches 54A and 54B. Metal lines 58A and 58B are thus formed higher than dielectric layer 24B.

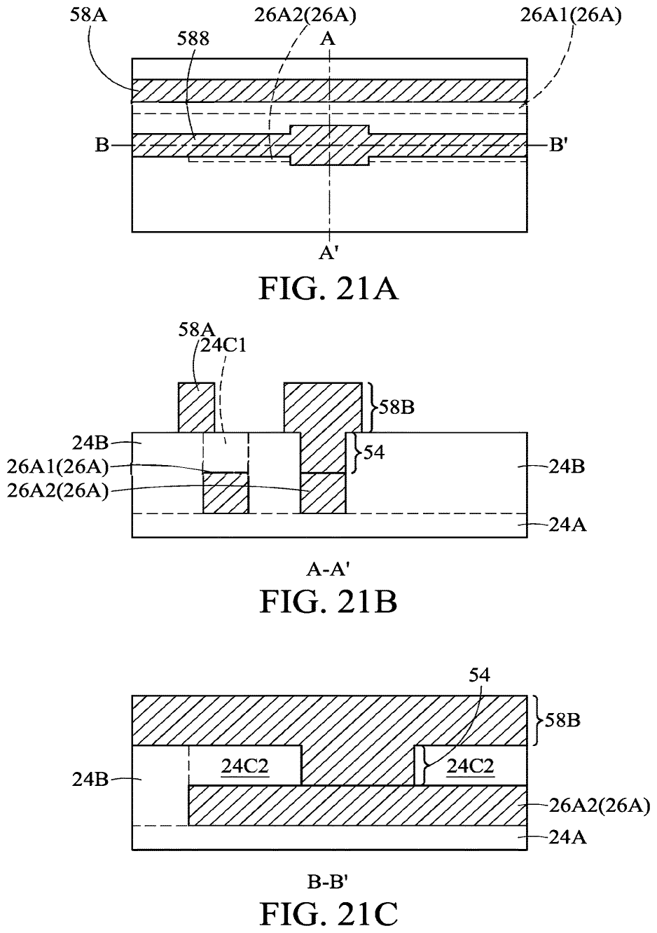

FIGS. 21A, 21B, and 21C illustrate the removal of mask 52, and the subsequent etching to remove exposed portions of metal seed layer 50. The remaining portions of metal seed layer 50 are considered as parts of metal lines 58A and 58B and via 54. Via 54 is formed underlying and joined to metal line 58B, with no distinguishable interface in between.

FIGS. 22A, 22B, and 22C illustrate the formation of dielectric layer 24D. In accordance with some embodiments, dielectric layer 24D may be formed of a material selected from the same group of candidate materials for forming dielectric layers 24A, 24B, and/or 24C. The material of dielectric layer 24D may also be the same as or different from the materials of dielectric layers 24A, 24B, and/or 24C. Dielectric layers 24A, 24B, 24C (including 24C1 and 24C2), and 24D are individually and collectively referred to as dielectric layers 24, which is also shown in FIG. 2.

In accordance with the embodiments of the present application, a high degree of alignment can be achieved to align the sidewalls of vias to the respective sidewalls of the corresponding underlying metal lines. For example, in the cross-section as shown in FIG. 22B, the sidewalls 54SW of via 54 are vertically aligned to the sidewalls 26A2SW of metal line 26A2. Furthermore, sidewalls 54SW and the respective underlying sidewalls 26A2SW are aligned to same straight lines in the cross-section as shown in FIG. 18C (also refer to FIGS. 27A and 27C).

The processes as shown in FIGS. 15A, 15B, and 15C through FIGS. 22A, 22B, and 22C illustrate the formation of via 54 and an upper metal line 58B from an intermediate portion (as shown in FIGS. 8A, 8B, and 8C) of an underlying metal line 26A2. In accordance with alternative embodiments, the same processes may also be performed to form via 54 and an upper metal line 58B from a line-end portion (as shown in FIGS. 14A, 14B, and 14C) of an underlying metal line 26A2. In the respective final structure, the via opening 44 (and thus the via 54 filling via opening 44) will have three sidewalls (with first two sidewalls shown in FIG. 14B and a third shown in FIG. 14C) vertically aligned to the sidewalls of the respective underlying metal line 26A2 without the concern of misalignment. The corresponding structure may be realized.

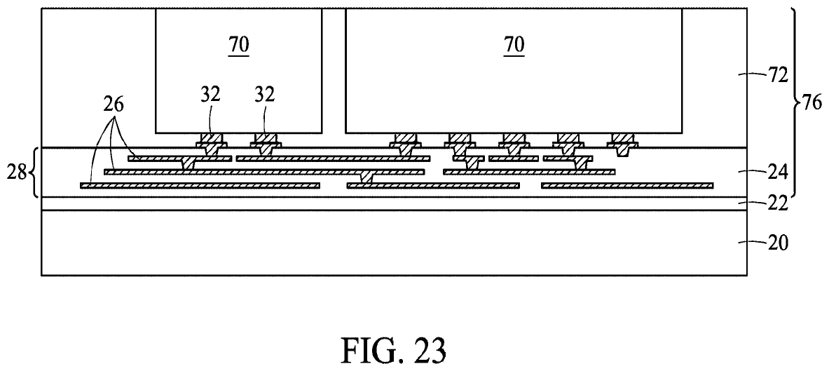

FIGS. 23 through 26 illustrate the remaining processes for forming a package in accordance with some embodiments. The process is continued from the structure shown in FIG. 2. As shown in FIG. 23, package components 70 are bonded to interconnect structure 28. Package components 70 may comprise device dies, packages, die stacks, or the like. Encapsulant 72 is formed to encapsulate package components 70 therein. Encapsulant 72 may comprise a molding compound, a underfill, a molding underfill, or the like. Package 76 is thus formed.

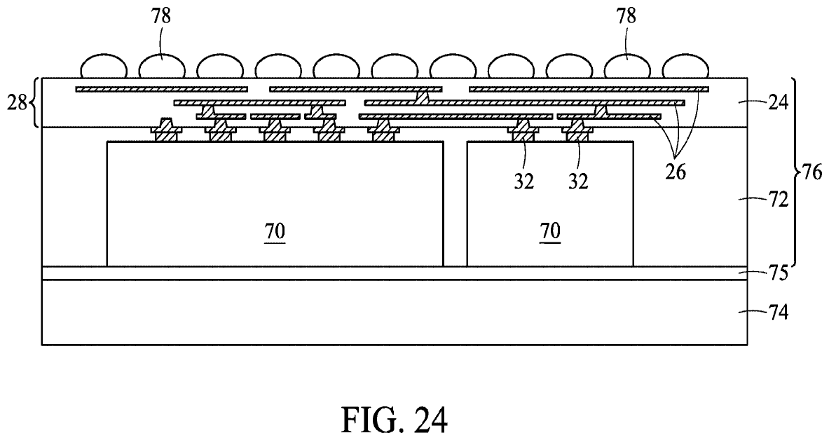

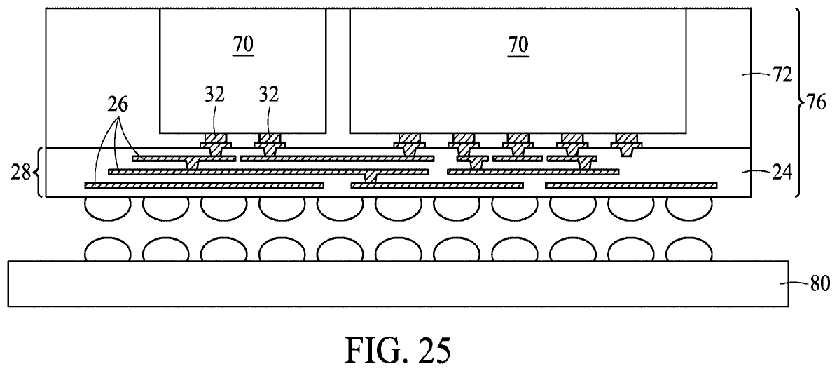

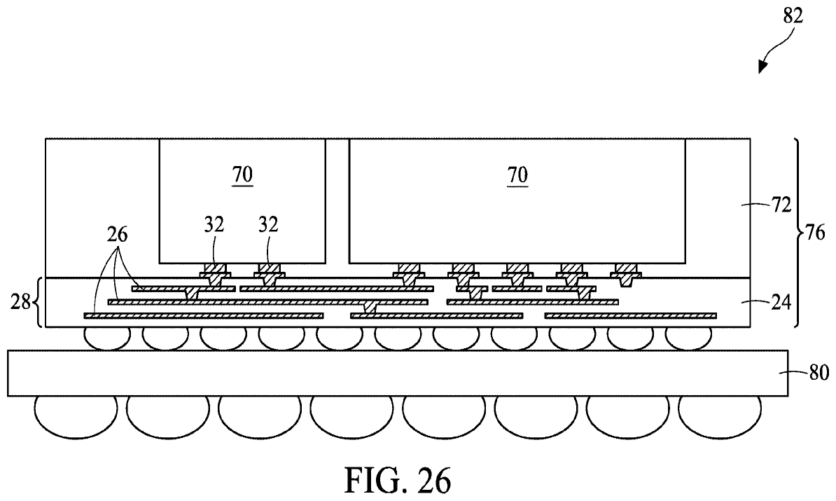

Next, as shown in FIG. 24, carrier 74 is attached to package 76 through release film 75, followed by the removal of carrier 20. Electrical connectors 78, which may comprise solder regions, are then formed as the surface features of package 76. FIGS. 25 and 26 illustrate the bonding of package 76 to package component 80 to form package 82.

FIGS. 27A, 27B, and 27C illustrate the sidewall profiles of vias and the underlying metal lines in accordance with some embodiments. FIG. 27A illustrates that the via 54 and metal line 26A2 have an inversed trapezoidal shape in the cross-section. FIG. 27B illustrates that the via 54 and metal line 26A2 have a rectangular shape in the cross-section. FIG. 27C illustrates that the via 54 and metal line 26A2 have a trapezoidal shape in the cross-section. The sidewalls 54SW of via 54 are aligned to, and have same tilt angles θ as the sidewalls 26A2SW of the respective underlying metal line 26A2. Furthermore, sidewalls 54SW are joined to sidewalls 26A2SW. Sidewalls 54SW and the corresponding underlying sidewalls 26A2SW are also aligned to straight lines in the cross-sectional views, wherein the straight lines are vertical or slanted.

In addition, the structures as shown in FIGS. 27A, 27B, and 27C may exist in the same device die. While the structures as shown in FIGS. 27A, 27B, and 27C are formed in the same dielectric layers 24A, 24B, 24C, and 24D, and the sidewalls of vias and the sidewalls of the respective underlying metal lines may be aligned to the same straight lines, the tilt angles θ of different redistribution lines may be different from each other, as shown in FIGS. 27A, 27B, and 27C.

Further due to the etch back process, as shown in FIG. 18C, the left end sidewall of metal line 26A2 and the left end sidewall of the left dielectric strip 24C2 are aligned to the same straight line, which may be vertical or slanted, similar to FIG. 27A or FIG. 27C. Also, when via 54 is formed aligned to a line end of metal line 26A2 (not shown), the end sidewall of metal line 26A2 and the end sidewall of via 54 will be are aligned to the same straight line, which may be vertical or slanted, similar to FIG. 27A or FIG. 27C.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By adopting a recessing process on a metal line to leave a recess/trench in a dielectric layer, and forming a via that is defined by the trench, the via is self-aligned to the metal line. The misalignment of via to the underlying metal line is eliminated. The pattern density of redistribution lines may be increased.

In accordance with some embodiments of the present disclosure, a method comprises forming a first metal line; forming a first dielectric layer, with the first metal line being in the first dielectric layer; etching back the first metal line to form a trench in the first dielectric layer, wherein a lower part of the first metal line remains under the trench; filling a photo sensitive material in the trench; performing a photolithography process to pattern the photo sensitive material, wherein a via opening is formed in the first dielectric layer and the photo sensitive material; and forming a second metal line and a via, wherein the via is formed in the via opening, and the second metal line is over and joined to the via.

In an embodiment, the method further comprises, before the photolithography process, performing a planarization process to level a first top surfaces of the photo sensitive material with a second top surface of the first dielectric layer. In an embodiment, the method further comprises, before the first metal line is etched back, performing a planarization process to level top surfaces of the first dielectric layer and the first metal line. In an embodiment, the trench and the lower part of the first metal line have a same length and a same width.

In an embodiment, the via opening has an end vertically aligned to a line end of the first metal line. In an embodiment, the via opening overlaps an intermediate part of the lower part of the first metal line. In an embodiment, the method further comprises, before the second metal line and the via are formed, curing the photo sensitive material. In an embodiment, the method further comprises forming a plating mask on the photo sensitive material that has been cured, wherein the second metal line and the via are plated from the plating mask.

In an embodiment, the method further comprises removing the plating mask; and forming a second dielectric layer over and contacting the photo sensitive material, with the second metal line being in the second dielectric layer. In an embodiment, the etching back the first metal line resulting in opposing sidewalls of the first dielectric layer to be exposed to the trench, and wherein after the via opening is formed, the opposing sidewalls of the first dielectric layer are exposed to the via opening.

In accordance with some embodiments of the present disclosure, a structure comprises a first metal line having a first sidewall and a second sidewall parallel to the first sidewall; a via overlying and contacting the first metal line, wherein the via comprises a third sidewall vertically aligned to the first sidewall, and a fourth sidewall vertically aligned to the second sidewall; a first dielectric layer, wherein the first metal line and the via are in the first dielectric layer; a second metal line over and joined to the via, wherein a bottom surface of the second metal line contacts a top surface of the first dielectric layer; and a second dielectric layer, wherein top surfaces of the second dielectric layer and the second metal line are coplanar.

In an embodiment, the via overlaps an intermediate portion of the first metal line. In an embodiment, the via overlaps a line end portion of the first metal line, and wherein the via further comprises a first end sidewall aligned to a second end sidewall of the first metal line. In an embodiment, the structure further comprises a third dielectric layer overlapping the first metal line, wherein the third dielectric layer comprises a fifth sidewall vertically aligned to the first sidewall, and a sixth sidewall vertically aligned to the second sidewall.

In an embodiment, the third dielectric layer comprises a photo sensitive material. In an embodiment, the second dielectric layer comprises a first lower portion in the first dielectric layer and contacting the third sidewall of the via. In an embodiment, the second dielectric layer further comprises a second lower portion in the first dielectric layer and contacting the fourth sidewall of the via. In an embodiment, both of the first dielectric layer and the second dielectric layer comprise organic materials.

In accordance with some embodiments of the present disclosure, a structure comprises a first metal line having a first sidewall and a second sidewall parallel to the first sidewall; a via overlying and contacting the first metal line, wherein the via comprises a third sidewall, wherein in a cross-section of the structure, the third sidewall and the first sidewall are aligned to a same first straight line; and a fourth sidewall, wherein in the cross-section of the structure, the fourth sidewall and the second sidewall are aligned to a same second straight line; and a second metal line over and joined to the via.

In an embodiment, the first metal line further comprises a first end sidewall, and the via further comprises a second end sidewall, and wherein in the cross-section of the structure, the first end sidewall and the second end sidewall are aligned to a same third straight line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first metal line;
forming a first dielectric layer, with the first metal line being in the first dielectric layer;
etching back the first metal line to form a trench in the first dielectric layer, wherein a lower part of the first metal line remains under the trench;
filling a dielectric strip in the trench;
removing a portion of the dielectric strip to form a via opening, wherein the via opening is encircled by portions of the first dielectric layer and the dielectric strip; and
forming a second metal line and a via, wherein the via is formed in the via opening, and the second metal line is over and joined to the via.

2. The method of claim 1, wherein after the trench is formed, the first dielectric layer comprises first four edges facing the trench, and wherein the first four edges are aligned to respective second four edges of the first metal line.

3. The method of claim 1, wherein the dielectric strip comprises a photo sensitive material, and wherein the removing the portion of the dielectric strip comprises a light-exposure process and a development process.

4. The method of claim 1, wherein the filling the dielectric strip comprises applying a dielectric material, and performing a planarization process to level a first top surface of the dielectric material with a second top surface of the first dielectric layer.

5. The method of claim 1 further comprising, before the first metal line is etched back, performing a planarization process to level top surfaces of the first dielectric layer and the first metal line.

6. The method of claim 1, wherein in a top view of the trench, the trench and the lower part of the first metal line have a same length and a same width.

7. The method of claim 1, wherein the via opening has an end vertically aligned to a line end of the first metal line.

8. The method of claim 1, wherein the via opening overlaps an intermediate part of the lower part of the first metal line.

9. The method of claim 1 further comprising, before the second metal line and the via are formed, curing the dielectric strip.

10. The method of claim 9 further comprising:
forming a plating mask over the dielectric strip, wherein the second metal line and the via are plated from the plating mask;
removing the plating mask; and
forming a second dielectric layer over and contacting the dielectric strip, with the second metal line being in the second dielectric layer.

11. The method of claim 1, wherein the etching back the first metal line is performed without using an etching mask to define a pattern of the trench.

12. A method comprising:
forming a first metal line;
forming a first dielectric layer, wherein the first metal line comprises a first edge and a second edge in contact with a third edge and a fourth edge, respectively, of the first dielectric layer;
recessing the first metal line to form a trench, so that the third edge and the fourth edge of the first dielectric layer are exposed to the trench;
filling the trench with a photo sensitive strip;
performing a planarization process on the photo sensitive strip, so that top surfaces of the photo sensitive strip and the first dielectric layer are coplanar;
performing a light-exposure process and a development process to remove a portion of the photo sensitive strip, so that a via opening is formed in the photo sensitive strip;
curing the photo sensitive strip; and
filling the via opening to form a conductive via.

13. The method of claim 12, wherein the filling the via opening comprises:
forming a metal seed layer over the first metal line and the photo sensitive strip;
forming a patterned plating mask over the metal seed layer; and
performing a plating process to form the conductive via and a second metal line over the conductive via.

14. The method of claim 12, wherein the conductive via overlaps an intermediate portion of the first metal line.

15. The method of claim 12, wherein the conductive via overlaps a line end portion of the first metal line.

16. The method of claim 12 further comprising, after the conductive via is formed, forming an additional dielectric layer to embed the conductive via.

17. A method comprising:
forming a first metal line;
forming a dielectric layer, wherein the first metal line is in the dielectric layer, and the first metal line has a height;
performing a planarization process to level top surfaces of the first metal line and the dielectric layer;
recessing the first metal line to form a trench, wherein a depth of the trench is smaller than the height of the first metal line;
forming a via in a part of the trench; and
forming a second metal line over and contacting the via.

18. The method of claim 17 further comprising
filling the trench with a photo sensitive strip; and
removing a portion of the photo sensitive strip to form the via opening.

19. The method of claim 18, wherein the removing the portion of the photo sensitive strip comprises a light-exposure process and a development process.

20. The method of claim 17, wherein when the first metal line is recessed, the dielectric layer is resistant to an etching chemical used for recessing the first metal line.
